(19) United States
(12) Patent Application Publication
(10) Pub. No.: US 2026/0029467 A1
(43) Pub. Date: Jan. 29, 2026

(54) MOTOR EMULATOR AND CONTROL METHOD OF MOTOR EMULATOR

(71) Applicant: Delta Electronics, Inc., Taoyuan City (TW)

(72) Inventors: Fang Yi LIN, Taoyuan City (TW); Ming Yuan HSIEH, Taoyuan City (TW); Yaow Ming CHEN, Taoyuan City (TW)

(73) Assignee: Delta Electronics, Inc., Taoyuan City (TW)

(21) Appl. No.: 18/937,145

(22) Filed: Nov. 5, 2024

(30) Foreign Application Priority Data
Jul. 29, 2024 (CN) 202411021815.8

(51) Int. Cl. G01R 31/34

(52) U.S. Cl. CPC G01R 31/343

(57) ABSTRACT

A motor emulator is configured to receive an electrical potential signal from a motor driver. The motor emulator includes control level circuit and power level circuit. The power level circuit at least includes an inductor, and an inverter circuit configured to provide an electrical potential to an output end of the inductor. The control level circuit is configured to generate a trigger signal based on an electrical potential change at an input end of the inductor and a current value passing through the inductor to trigger an electrical potential change provided by the inverter circuit to the output end of the inductor, so that the electrical potential at the output end of the inductor follows the electrical potential change at an input end of the inductor to adjust the current through the inductor. The motor emulator reduces switching loss.

### RELATED APPLICATION

This application claims the benefit of priority of China Patent Application No. 202411021815.8 filed on Jul. 29, 2024, the contents of which are incorporated by reference as if fully set forth herein in their entirety.

### FIELD

The disclosure relates to motor emulator, and more particularly, to a motor emulator and a control method of a motor emulator.

### BACKGROUND

The power test of conventional motor drivers requires establishment of a complex test platform, including motors of certain specifications, mechanical loads, and controllers, etc. It has shortcomings such as high test cost, time-consuming, high noise, and bulkiness, and it also requires high wattage consumption. The test environment is not flexible enough. To overcome these limitations, motor emulators have been developed in recent years as an alternative.

In the conventional technology, the switching frequency of the motor emulator is generally at least higher than the switching frequency of the motor driver. Most of they use about five to ten times the switching frequency of the motor driver. The advantage of using higher frequency is that it is easy to control the current, but the switching loss will be relatively high. Therefore, there is a need to solve the above-mentioned loss issue of the motor emulator.

### SUMMARY

In view of the above, the disclosure provides a motor emulator and a control method of a motor emulator to effectively solve the issue of high switching loss of the motor emulator in the prior art.

In order to achieve above-mentioned object of the disclosure, one embodiment of the disclosure provides a control method of a motor emulator, including: receiving an electrical potential signal of a motor driver by a power level circuit of a motor emulator, wherein the power level circuit at least includes an inductor, and an input end of the inductor is configured to receive the electrical potential signal of the motor driver; and providing a trigger signal based on a change of electrical potential at the input end of the inductor and a value of a current passing through the inductor to determine a change of electrical potential at an output end of the inductor, so that an electrical potential at the output end of the inductor follows the change of the electrical potential at the input end of the inductor to adjust the current passing through the inductor.

In one embodiment of the control method of the motor emulator, the step of providing the trigger signal based on the change of the electrical potential at the input end of the inductor and the value of the current passing through the inductor to determine the change of the electrical potential at the output end of the inductor includes: when the value of the current passing the inductor is less than a preset current value and the electrical potential at the input end of the inductor changes from low to high, the motor emulator keeps a low electrical potential at the output end of the inductor for a preset duration and then changes the electrical potential from low to high.

In one embodiment of the control method of the motor emulator, the step of providing the trigger signal based on the change of the electrical potential at the input end of the inductor and the value of the current passing through the inductor to determine the change of the electrical potential at the output end of the inductor includes: when the value of the current passing the inductor is less than a preset current value and the electrical potential at the input end of the inductor changes from high to low, the motor emulator provides the trigger signal immediately to change the electrical potential at the output end of the inductor from high to low.

In one embodiment of the control method of the motor emulator, the step of providing the trigger signal based on the change of the electrical potential at the input end of the inductor and the value of the current passing through the inductor to determine the change of the electrical potential at the output end of the inductor includes: when the value of the current passing the inductor is greater than a preset current value and the electrical potential at the input end of the inductor changes from low to high, the motor emulator provides the trigger signal immediately to change the electrical potential at the output end of the inductor from low to high.

In one embodiment of the control method of the motor emulator, the step of providing the trigger signal based on the change of the electrical potential at the input end of the inductor and the value of the current passing through the inductor to determine the change of the electrical potential at the output end of the inductor includes: when the value of the current passing the inductor is greater than a preset current value and the electrical potential at the input end of the inductor is changed from high to low, the motor emulator keeps a high electrical potential at the output end of the inductor for a preset duration and then changes the electrical potential from high to low.

Another embodiment of the disclosure provides a motor emulator configured to receive an electrical potential signal of a motor driver, including: a power level circuit and a control level circuit. The power level circuit at least includes an inductor and an inverter circuit configured to provide an electrical potential to an output end of the inductor. The control level circuit is configured to provide a trigger signal based on the change of electrical potential at an input end of the inductor and a value of a current passing through the inductor to determine the change of the electrical potential at the output end of the inductor, so that an electrical potential at the output end of the inductor follows the change of the electrical potential at the input end of the inductor to adjust the current passing through the inductor.

In one embodiment of the power module, the control level circuit is configured to control the inverter circuit to keep a low electrical potential at the output end of the inductor for a preset duration and then changes the electrical potential from low to high when the value of the current passing the inductor is less than a preset current value and the electrical potential at the input end of the inductor is changed from low to high.

In one embodiment of the power module, the control level circuit is configured to provide the trigger signal immediately to control the inverter circuit to change the electrical potential at the output end of the inductor from high to low when the value of the current passing the inductor is less than a preset current value and the electrical potential at the input end of the inductor is changed from high to low.

In one embodiment of the power module, the control level circuit is configured to provide the trigger signal immediately to control the inverter circuit to change the electrical potential at the output end of the inductor from low to high when the value of the current passing the inductor is greater than a preset current value and the electrical potential at the input end of the inductor is changed from low to high.

In one embodiment of the power module, the control level circuit is configured to control the inverter circuit to keep a high electrical potential at the output end of the inductor for a preset duration and then changes the electrical potential from high to low when the value of the current passing the inductor is greater than a preset current value and the electrical potential at the input end of the inductor is changed from high to low.

In one embodiment of the power module, the control level circuit includes: a voltage sensing module, a current sensing module, a motor model library, and a control module, the voltage sensing module is configured to detect the change of electrical potential at the input end of the inductor, the current sensing module is configured to detect the current passing through the inductor, and the control module is configured to retrieve current data corresponding to the preset motor model from the motor model library based on the electrical potential detected by the voltage sensing module and compare it with the current value obtained by the current sensing module to provide the trigger signal.

In one embodiment of the power module, the control level circuit further includes a pulse width modulation module configured to provide pulse width modulation signal to turn on or off the inverter circuit based on a signal from the control module and change of electrical potential at the input end of the inductor.

In one embodiment of the power module, the power level circuit includes a DC voltage supply module to provide the electrical potential at the output end of the inductor through the inverter circuit.

In one embodiment of the power module, the DC voltage supply module and a DC voltage supply module of the motor driver are grounded together and provide a same DC electrical potential.

In one embodiment of the power module, the DC voltage supply module and a DC voltage supply module of the motor driver are grounded together and provide different DC electrical potentials, and the power level circuit further includes a zero sequence filter circuit disposed between the output end of the inductor and the inverter circuit.

In one embodiment of the power module, the DC voltage supply module and a DC voltage supply module of the motor driver are isolated from each other.

In comparison with prior art, the disclosed motor emulator provides the trigger signal based on the change of electrical potential at an input end of the inductor and a value of a current passing through the inductor to control the inverter circuit to change the electrical potential at the output end of the inductor, so that an electrical potential at the output end of the inductor follows the change of the electrical potential at the input end of the inductor to adjust the current passing through the inductor. The motor emulator can operator at the same switching frequency with the motor driver without further signal from the motor driver. The motor emulator can on one hand switch the current with lower frequency to reduce switching lose and on the other hand compensates current error rapidly to increase accuracy of current control and avoid the issue in the prior art.

### BRIEF DESCRIPTION OF DRAWINGS

FIG. 1 is a schematic view of a circuit structure of a motor emulator according to a first embodiment of the disclosure;

FIG. 2 is schematic diagram of a voltage and a current waveforms corresponding to the motor driver and the motor emulator under current error condition in the control method of the motor emulator according to one embodiment of the disclosure;

FIG. 3 is schematic diagram of a voltage and a current waveforms corresponding to the motor driver and the motor emulator under different current error condition in the control method of the motor emulator according to another embodiment of the disclosure;

FIG. 4 is a schematic view of a circuit structure of a motor emulator according to a first embodiment of the disclosure;

FIG. 5 is a current waveform at a frequency of 10 kHz of a motor emulator according to an embodiment of the disclosure in a simulation scenario;

FIG. 6 is a current waveform at a frequency of 10 kHz of a motor emulator according to another embodiment of the disclosure in a simulation scenario;

FIG. 7 is a schematic flowchart illustrating a control method of a motor emulator according to one embodiment of the disclosure;

FIG. 8 is a schematic flowchart illustrating a control method of a motor emulator according to one embodiment of the disclosure;

FIG. 9 is a schematic flowchart illustrating a control method of a motor emulator according to another embodiment of the disclosure;

FIG. 10 is a schematic diagram of rotor speed in a simulation scenario of a motor emulator and a motor driver according to one embodiment of the disclosure;

FIG. 11 is a schematic diagram of three-phase current in the simulation scenario of FIG. 10;

FIG. 12 is a schematic torque diagram in the simulation scenario of FIG. 10;

FIG. 13 is a schematic diagram illustrating the simulation results of the current error in the simulation scenario of FIG. 10;

FIG. 14 illustrates a comparison of the simulated current waveforms of a motor emulator using a switching frequency of 10 kHz according to an embodiment of the disclosure and a motor emulator using a frequency of 100 kHz in the prior art when the rotor is accelerating;

FIG. 15 illustrates a comparison of simulated current waveforms during rotor deceleration between a motor emulator according to an embodiment of the disclosure and a motor emulator of the prior art;

FIG. 16 illustrates a comparison of simulated current waveforms between a motor emulator according to an embodiment of the disclosure and a motor emulator of the prior art when the rotor speed is 600 rpm, and the torque is 50 Newton meters;

FIG. 17 illustrates a comparison of the simulated current waveforms of a motor emulator according to an embodiment of the disclosure and a motor emulator of the prior art when the rotor speed is 600 rpm, and the torque is 100 Newton meters;

FIG. 18 illustrates a simulated current waveform at a frequency of 100 kHz by a motor emulator according to the prior art; and

FIG. 19 illustrates a simulated current waveform at a frequency of 10 kHz by a motor emulator according to the prior art.

### REFERENCE NUMERALS DESCRIPTION

EME, EME′: motor emulator; DUT: motor driver; PL: power level circuit; CL: control level circuit; IV, IV′: inverter circuit; VS: voltage sensing module; CS, CS′: current sensing module; PM, PM′: pulse width modulation module; CT, CT′: control module; MM: motor model library; v, V′, v1, v2: DC voltage supply module; ZF: zero sequence filter circuit; In-a, In-b, In-c: inductor; Ia: current; Ve-a, Ve-b, Ve-c: electrical potential at output end; Vd-a, Vd-b, Vd-c: electrical potential at input end; S_{E,Φ}, S_{D,Φ}: trigger signal; S100-S262: steps.

### DETAILED DESCRIPTION

In order to make the above and other objects, features, and advantages of the disclosure easier to understand, preferred embodiments of the disclosure will be illustrated below and described in detail with reference to the drawings. In addition, in the drawings, structurally similar units are represented by the same reference numerals.

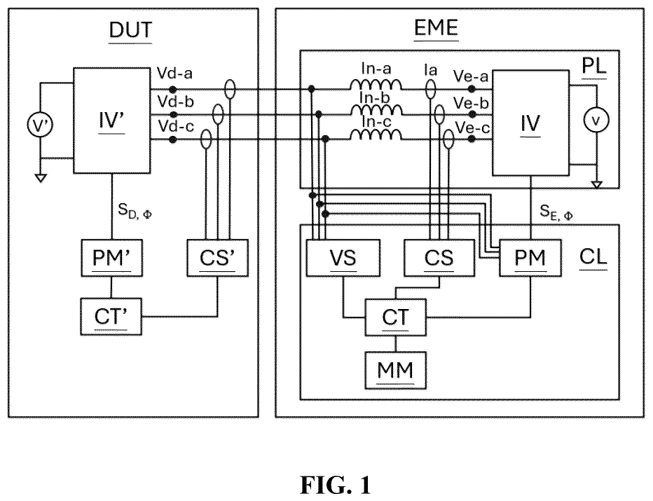

Referring to FIG. 1, it is a schematic circuit structure diagram of a motor emulator according to one embodiment of the disclosure. The disclosure provides a motor emulator EME for receiving electrical potential signals (Vd-a, Vd-b, Vd-c) of a motor driver DUT. The motor emulator EME includes a control level circuit CL and a power level circuit PL. The power level circuit PL at least includes an inductor In-a and an inverter circuit IV used to provide an electrical potential Ve-a at an output end of the inductor In-a. The control level circuit CL is configured to provide a trigger signal S_{E,Φ} based on change of the electrical potential Vd-a at an input end of the inductor In-a and value of current Ia passing through the inductor In-a to trigger a change of electrical potential Ve-a provided by the inverter circuit IV to the output end the inductor In-a, so that the electrical potential Ve-a at the output end of the inductor In-a follows the change of the electrical potential Vd-a at the input end of the inductor In-a to adjust the current Ia passing through the inductor In-a.

In detail, the power level circuit PL is, for example, an equivalent circuit of a motor, including, for example, three inductors In-a, In-b, and In-c. For example, the inverter circuit IV includes three power switches corresponding to the inductors In-a, In-b, and In-c respectively to supply the voltages Ve-a, Ve-b, and Ve-c corresponding to the inductors In-a, In-b, and In-c. The power switches are, for example, power semiconductor switching elements. The following is based on the a-phase circuit. The b-phase or c-phase circuit is the same as the a-phase circuit. Please refer to the description of the a-phase circuit.

Referring to FIG. 1, in one embodiment of the disclosure, the control level circuit CL includes: a voltage sensing module VS, a current sensing module CS, a motor model library MM, and a control module CT. The voltage sensing module VS is configured to detect changes of the electrical potential Vd-a at the input end of the inductor In-a. The current sensing module CS is configured to detect the current value Ia passing through the inductor In-a. The control module CT is configured to retrieve current data of the preset motor model corresponding to the electrical potential Vd-a detected by the voltage sensing module VS from the motor model library MM and compare it with the current value Ia obtained by the current sensing module CS to provide the trigger signal S_{E,Φ}.

In detail, the motor model library MM stores data of multiple motor models, such as operating voltage and operating current of the motors. So that users can use the motor emulator EME to simulate different motors. When the user selects a motor model (called a preset motor model), the control module CT retrieves current data (called a preset current value) corresponding to the electrical potential detected by the voltage sensing module VS from the preset motor model and compared with value of the current Ia obtained by the current sensing module CS.

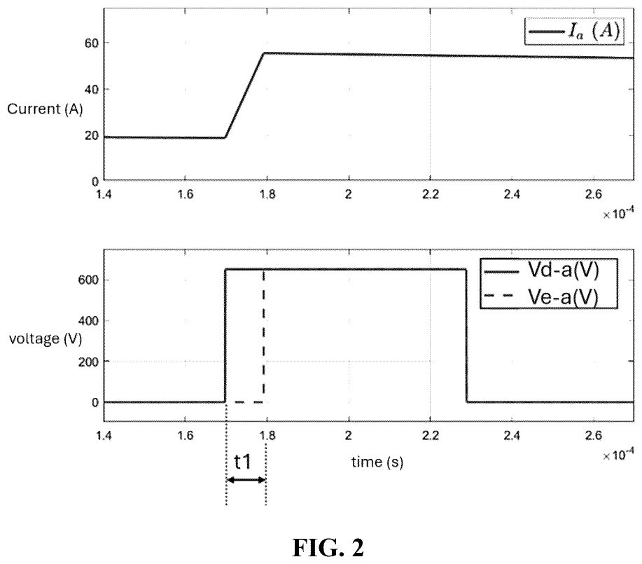

FIG. 2 is a schematic diagram of the corresponding voltage and current waveforms of the motor driver and the motor emulator under current error conditions in the control method of the motor emulator according to an embodiment of the disclosure. Please refer to FIGS. 1 and 2 together, in one embodiment of the disclosure, the control level circuit CL is configured to control the inverter circuit IV to keep the electrical potential Ve-a at the output end of the inductor In-a low for compensation time t1 and then changes it from low potential to high potential when the current Ia of the inductor In-a is sensed to be less than a preset current value, and the electrical potential Vd-a at the input end of the inductor In-a is changed from low potential to high potential.

In detail, according to the operating principle of the inductor, if the electrical potential at the input end of the inductor is greater than the electrical potential at the output end of the inductor, the value of current flowing through the inductor will increase. Therefore, when the control level circuit CL senses that the current Ia of the inductor In-a is less than a preset current value (the current value that the preset motor model should have when the electrical potential Vd-a is sensed at the input end of the inductor), the control level circuit CL controls the inverter circuit IV to keep the electrical potential Ve-a at the output end of the inductor In-a low for a compensation time t1 and then following the change of the electrical potential Vd-a at the input end to a high potential. The current Ia flowing through the inductor In-a is increased through this operation to obtain compensation. The value of the compensation time t1 can be determined by the difference between the current Ia of the inductor In-a and the preset current value, the difference between the electrical potential Vd-a at the input end and the electrical potential Ve-a at the output end, and the inductance of the inductor In-a. The value is determined to reduce the error of the current simulated by the motor emulator EME.

Referring to FIGS. 1 and 2, in one embodiment of the disclosure, the control level circuit CL is configured to provide the trigger signal S_{E,Φ} immediately to control the inverter circuit IV to change the electrical potential Ve-a at the output end of the inductor In-a from high potential to low potential when the current Ia of the inductor In-a is sensed to be less than a preset current value, and electrical potential Vd-a at the input end of the inductor In-a is changed from high potential to low potential.

In detail, according to the operating principle of the inductor, if electrical potential at the input end of the inductor is equal to electrical potential at the output end of the inductor, the value of current flowing through the inductor remains unchanged. If the electrical potential at the input end of the inductor is lower than the electrical potential at the output end of the inductor, the current flowing through the inductor will decrease. Therefore, when the control level circuit CL senses that the current Ia of the inductor In-a is less than a preset current value (the current value that the preset motor model should have when the input end has the potential Vd-a), that the control level circuit CL controls the inverter circuit IV to maintain the high potential Ve-a at the output end of the inductor In-a for a compensation time and then following the change of the electrical potential Vd-a at the input end to a low level will cause the value of the current Ia lower than the preset current even lower and the simulation state of the motor is deteriorated. Therefore, the method of this embodiment immediately generates the trigger signal S_{E,Φ} to control the inverter circuit IV to change the electrical potential Ve-a at the output end of the inductor In-a from high potential to low potential to maintain the current Ia of the inductor In-a from deteriorating.

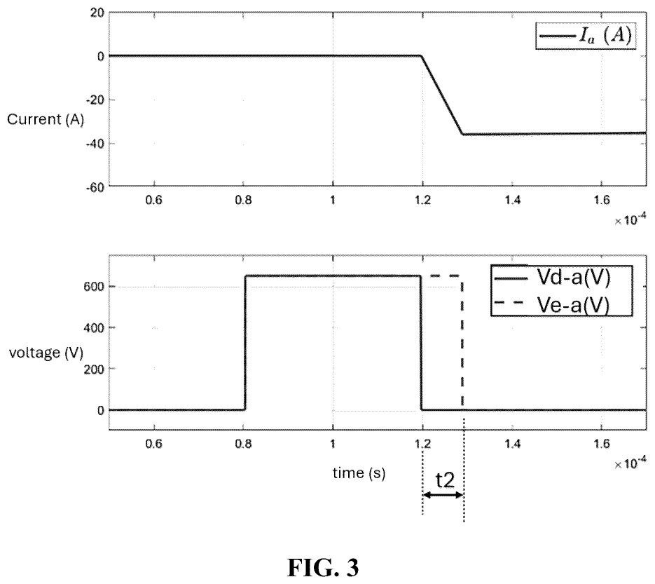

FIG. 3 illustrates a schematic diagram of the corresponding voltage and current waveforms of the motor driver and the motor emulator under different current error conditions in the control method of the motor emulator according to another embodiment of the disclosure. Referring to FIG. 1 and FIG. 3, in one embodiment of the disclosure, the control level circuit CL is configured to provide the trigger signal S_{E,Φ} immediately to control the inverter circuit IV to change the electrical potential Ve-a at the output end of the inductor In-a from low potential to high potential when it senses that the current Ia of the inductor In-a is greater than a preset current value, and the electrical potential Vd-a at the input end the inductor In-a is changed from low potential to high potential,

In detail, according to the operating principle of the inductor, if the electrical potential at the input end of the inductor is equal to the electrical potential at the output end of the inductor, the value of current flowing through the inductor remains unchanged. If the electrical potential at the input end of the inductor is greater than the electrical potential at the output end of the inductor, the current flowing through the inductor will increase. Therefore, when the control level circuit CL senses that the current Ia of the inductor In-a is greater than a preset current value (the current value that the preset motor model should have when the input end has the electrical potential Vd-a), the control level circuit CL immediately generate the trigger signal S_{E,Φ} to controls the inverter circuit IV to change the electrical potential Ve-a at the output end of the inductor In-a from a low potential to a high potential. The current Ia flowing through the inductor In-a remains unchanged through this operation. If the control level circuit CL controls the inverter circuit IV to maintain the low electrical potential Ve-a at the output end of the inductor In-a for a compensation time and then following the change of the input end potential Vd-a to a high potential, it will cause the current Ia higher than the preset current value increasing further, thereby deteriorating the simulation state of the motor. Therefore, in this embodiment, the current Ia flowing through the inductor In-a remains unchanged through this operation, and the current Ia of the inductor In-a can be maintained from deteriorating.

Referring to FIG. 1 and FIG. 3, in one embodiment of the disclosure, the control level circuit CL is configured to control the inverter circuit IV to maintain the electrical potential Ve-a at the output end of the inductor In-a high for a compensation time t2 and then changes it to low potential when the current Ia of the inductor In-a is sensed to be greater than a preset current value, and the electrical potential Vd-a at the input end of the inductor In-a is changed from a high potential to a low potential.

In detail, according to the operating principle of the inductor, if the electrical potential at the input end of the inductor is less than the electrical potential at the output end of the inductor, the current value flowing through the inductor will decrease. Therefore, when the control level circuit CL senses that the current Ia of the inductor In-a is greater than a preset current value (the current value that the preset motor model should have when the input end has the electrical potential Vd-a), the control level circuit CL controls the inverter circuit IV to maintain the high electrical potential at the output end potential Ve-a of the inductor In-a for a compensation time and then follows the change of the electrical potential Vd-a at the input end to a low potential. The current Ia flowing through the inductor In-a is reduced through this operation to obtain compensation. The value of the compensation time t2 can be determined by the difference between the current Ia of the inductor In-a and the preset current value, the difference between the electrical potential Vd-a at the input end and the electrical potential Ve-a at the output end, and the inductance of the inductor In-a. The value is determined to reduce the error of the current simulated by the motor emulator EME.

Referring to FIG. 1, in one embodiment of the disclosure, the control level circuit also includes a pulse width modulation module PM. The pulse width modulation module PM is configured to provide a pulse width modulation signal (trigger signal S_{E,Φ}) according to the signal of the control module CT and the change of the electrical potential Vd-a at the input end of the inductor In-a and controls whether the inverter circuit IV is turned on or not.

In detail, the input signal of the pulse width modulation module PM includes the electrical potential Vd-a at the input end of the inductor In-a, so that the pulse width modulation signal can follow changes of the electrical potential Vd-a at the input end of the inductor In-a. The detail of the signal follow methods are as mentioned above, including immediate follow and delayed follow after a preset time. This design can synchronize the switching frequency of the electrical potential signal of the motor emulator EME and the motor driver DUT, eliminating the need to use a switching frequency of the motor emulator EME that is five to ten times the switching frequency of the motor driver, thereby reducing switching losses.

Referring to FIG. 1, in one embodiment of the disclosure, the power level circuit PL includes a DC voltage supply module v for providing the electrical potential Ve-a at the output end of the inductor In-a through the inverter circuit IV.

Referring to FIG. 1, in one embodiment of the disclosure, the DC voltage supply module v and the DC voltage supply module V′ of the motor driver DUT are grounded together and provide the same DC electrical potential.

Referring to FIG. 1, in detail, in one embodiment of the disclosure, the motor driver DUT includes an inverter circuit IV′, a current sensing module CS′, a pulse width modulation module PM′, and a control module CT′. The control module CT′ controls the pulse width modulation module PM′ to provide the trigger signal S_{D,Φ} to the inverter circuit IV′ based on the sensing result of the current sensing module CS′. The motor driver DUT is not the focus of this disclosure, and the structure of the motor driver DUT in FIG. 1 is only an embodiment. This disclosure is not limited thereto.

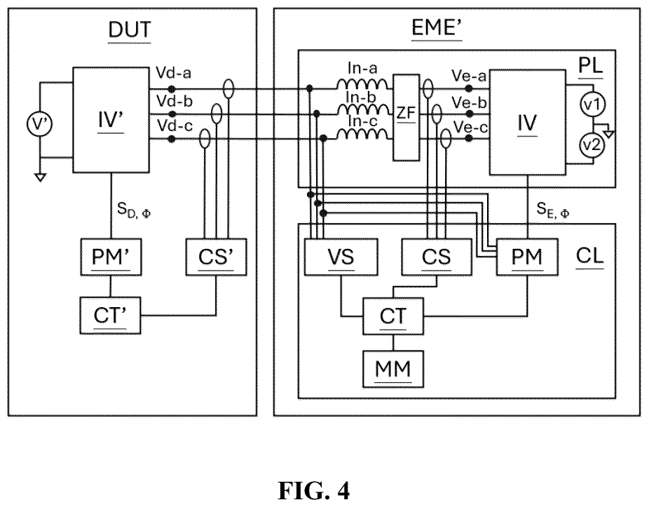

Referring to FIG. 4, it is a schematic circuit structure diagram of the motor emulator EME′ according to another embodiment of the disclosure. In one embodiment of the disclosure, the DC voltage supply modules v1 and v2 are grounded together with the DC voltage supply module V′ of the motor driver DUT and provide different DC potentials. The power level circuit PL also includes a zero sequence filter circuit ZF is disposed between the output end of the inductor In-a and the inverter circuit IV.

In detail, when the DC voltage supply modules v1, v2 and the DC voltage supply module V′ of the motor driver DUT are grounded together, zero sequence current (leakage current) will be generated, and a zero sequence filter circuit ZF needs to be set up. However, the motor emulator according to one embodiment of the disclosure has the effect of smaller zero-sequence current. Therefore, in the embodiment shown in FIG. 1 in which the DC voltage supply module has a common ground and the same DC electrical potential, the zero-sequence current is smaller. There is no need to set the zero sequence filter circuit ZF. In the embodiment shown in FIG. 4 in which the DC voltage supply module has a common ground and different DC potentials, the zero sequence current is relatively large, and a zero sequence filter circuit ZF can be set between the output end of the inductor In-a and the inverter circuit IV.

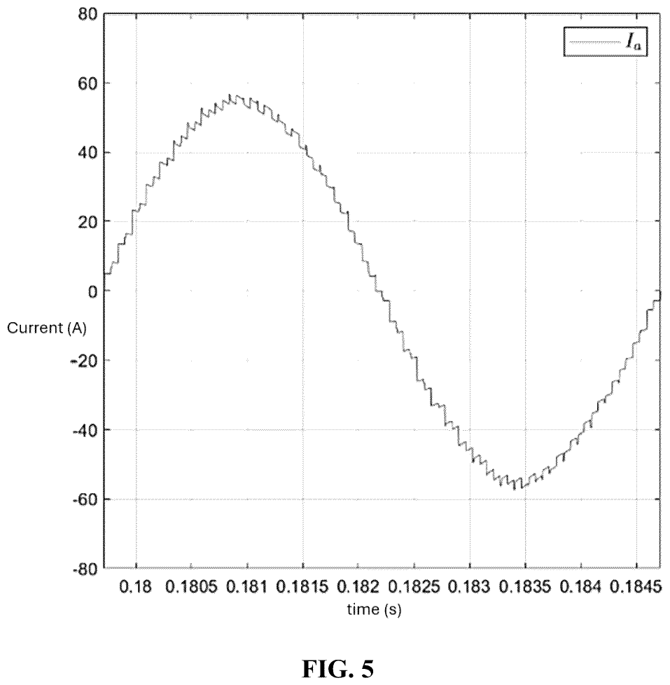

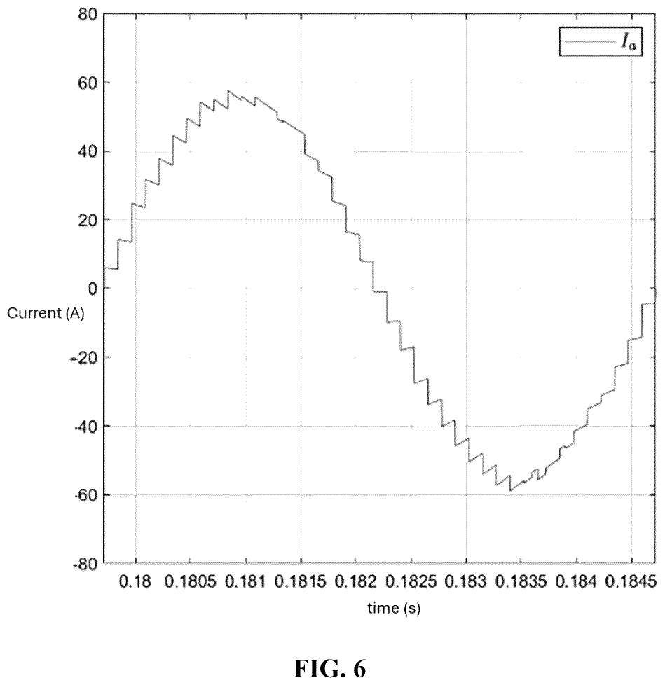

Referring to FIG. 5, it illustrates the current waveform of the motor emulator at a switching frequency of 10 kHz according to one embodiment of the disclosure in a simulation scenario, that is, the current waveform when the zero sequence filter circuit ZF is installed in the circuit of FIG. 1 in a simulation scenario in which the DC voltage supply modules are grounded together and has the same DC potential. Referring also to FIG. 6, it illustrates a current waveform at a switching frequency of 10 kHz of a motor emulator according to another embodiment of the disclosure under a simulation scenario, that is, the current waveform when the zero sequence filter circuit ZF is not set in the circuit of FIG. 1 in a simulation scenario in which the DC voltage supply module is grounded together and the DC potential is the same. It can be clearly seen from FIGS. 5 and 6 that the current signal ripple in FIG. 6 without the zero sequence filter circuit ZF is slightly larger, but it is not much different from the current signal ripple in FIG. 5.

In one embodiment of the disclosure, the DC voltage supply module and the DC voltage supply module of the motor driver are isolated from each other. In this embodiment, there is no need to set up a zero-sequence filter circuit in the motor emulator no matter whether the DC potentials of the DC voltage supply module of the motor emulator and the DC voltage supply module of the motor driver are the same, because the DC voltage supply module and the DC voltage supply module of the motor driver are mutually isolated, no zero-sequence current will be generated.

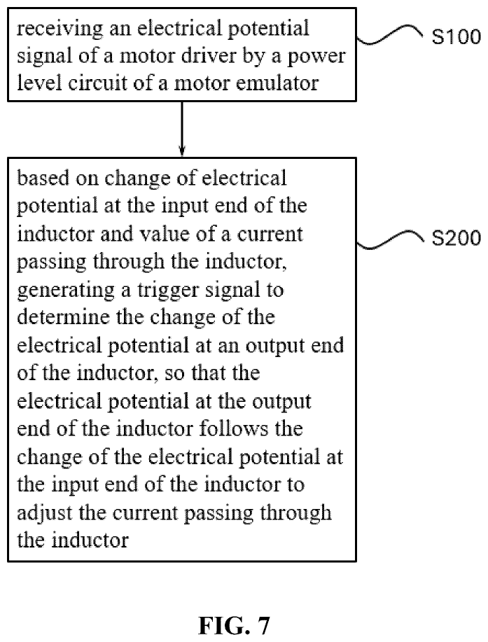

Referring to FIG. 7, a schematic flowchart of a control method of a motor emulator according to one embodiment of the disclosure is shown. Please also refer to FIG. 1, the disclosure provides a control method for a motor emulator EME, including: step S100: using a power level circuit PL of a motor emulator EME to receive a electrical potential signal Vd-a of a motor driver DUT, wherein the power level circuit PL at least includes an inductor In-a, and an input end of the inductor In-a receives the electrical potential signal Vd-a of the motor driver DUT; and step S200: based on change of electrical potential at the input end of the inductor In-a and value of a current Ia passing through the inductor In-a, generating a trigger signal S_{E,Φ} to determine the change of the electrical potential Ve-a at an output end of the inductor In-a, so that the electrical potential Ve-a at the output end of the inductor In-a follows the change of the electrical potential Vd-a at the input end of the inductor In-a to adjust the current Ia passing through the inductor In-a.

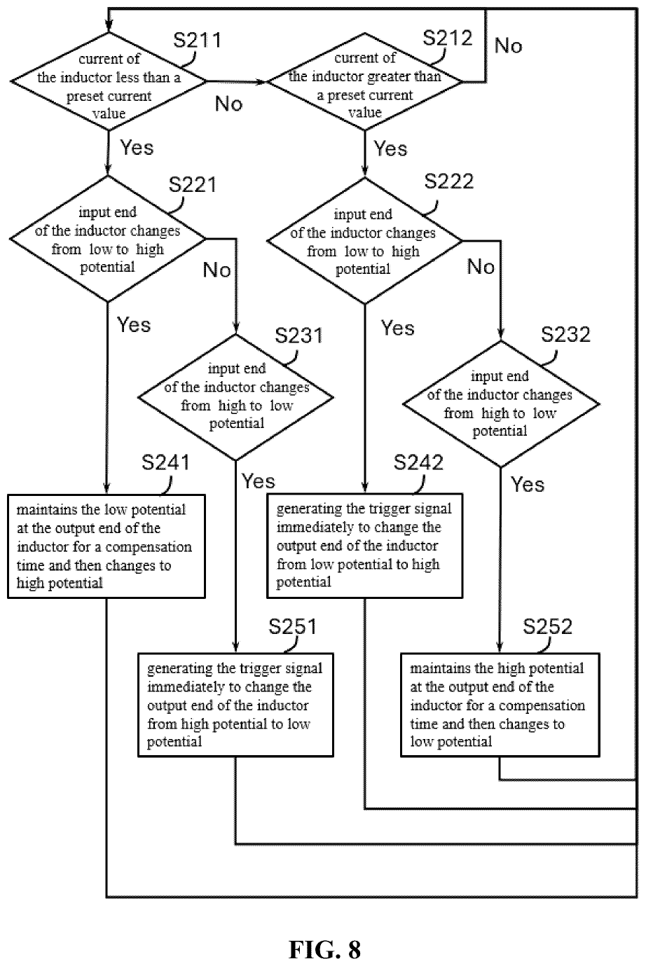

Referring to FIG. 8, a schematic flowchart of a control method of a motor emulator according to one embodiment of the disclosure is shown. Refer to FIG. 1 and FIG. 8. In one embodiment of the disclosure, the step S200 that based on change of electrical potential at the input end of the inductor In-a and value of a current Ia passing through the inductor In-a, generating a trigger signal S_{E,Φ} to determine the change of the electrical potential Ve-a at an output end of the inductor In-a includes: step S211: when it is sensed that the current Ia of the inductor In-a is less than a preset current value, and step S221: the input end of the inductor In-a changes from a low potential to a high potential (as Vd-a in FIG. 2), execute the step S241: the motor emulator circuit EME maintains the low potential at the output end of the inductor In-a for a compensation time t1 and then changes from low potential to high potential (as Ve-a in FIG. 2).

In detail, according to the operating principle of the inductor, if the electrical potential at the input end of the inductor is greater than the electrical potential at the output end of the inductor, the value of the current flowing through the inductor will increase. Therefore, when the control level circuit CL senses that the current Ia of the inductor In-a is less than a preset current value (the current value that the preset motor model should have when the input end has the electrical potential Vd-a), the control level circuit CL controls the inverter circuit IV to maintain the electrical potential Ve-a at the output end of the inductor In-a low for a compensation time t1 and then following the change of the electrical potential Vd-a at the input end to a high potential. The current Ia flowing through the inductor In-a is increased through this operation to obtain compensation. The value of the compensation time t1 can be determined by the difference between the current Ia of the inductor In-a and the preset current value, the difference between the electrical potential Vd-a at the input end and the electrical potential Ve-a at the output end, and the inductance of the inductor In-a. The value is determined to reduce the error of the current simulated by the motor emulator EME.

Refer to FIG. 1, FIG. 2 and FIG. 8. In one embodiment of the disclosure, the step of providing the trigger signal S_{E,Φ} according to the change of the electrical potential Vd-a at the input end of the inductor In-a and the current value Ia passing through the inductor In-a to determine the change of the electrical potential Ve-a at the output end of the inductor In-a includes: step S211: when it is sensed that the current Ia of the inductor In-a is less than a preset current value, and step S231: the electrical potential at the input end of the inductor In-a changes from high potential to low potential (as Vd-a in FIG. 2), execute step S251: immediately generate the trigger signal to change the output end of the inductor from a high potential to a low potential (as Ve-a in FIG. 2).

In detail, according to the operating principle of the inductor, if the electrical potential at the input end of the inductor is equal to the electrical potential at the output end of the inductor, the value of current flowing through the inductor remains unchanged. If the electrical potential at the input end of the inductor is lower than the electrical potential at the output end of the inductor, the current flowing through the inductor will decrease. Therefore, when the control level circuit CL senses that the current Ia of the inductor In-a is less than a preset current value (the current value that the preset motor model should have when the input end has the electrical potential Vd-a), the control level circuit CL controls the inverter circuit IV to maintain the electrical potential Ve-a at the output end of the inductor In-a high for a compensation time and then following the change of the electrical potential Vd-a at the input end to a low level will cause the current Ia lower than the preset value is even lower and the simulation state of the motor is deteriorated. Therefore, this embodiment uses the method of immediately generating the trigger signal S_{E,Φ} to control the inverter circuit IV to change the electrical potential Ve-a at the output end of the inductor In-a from a high potential to a low potential, thereby maintaining the current Ia of the inductor In-a from deteriorating.

Refer to FIG. 3 and FIG. 8. In one embodiment of the disclosure, The step of generating the trigger signal S_{E,Φ} according to the change of the electrical potential Vd-a at the input end of the inductor In-a and the value of current Ia passing through the inductor In-a to determine the change of the electrical potential Ve-a at the output end of inductor In-a includes: step S212: when it is sensed that the current Ia of the inductor In-a is greater than a preset current value, and step S222: When the electrical potential at the input end of the inductor In-a changes from low potential to high potential (as Vd-a in FIG. 3), execute step S242: generating the trigger signal S_{E,Φ} immediately to change the output end of the inductor In-a from low potential to high potential (as Ve-a in FIG. 3).

In detail, according to the operating principle of the inductor, if the electrical potential at the input end of the inductor is equal to the electrical potential at the output end of the inductor, the value of the current flowing through the inductor remains unchanged. If the electrical potential at the input end of the inductor is greater than the electrical potential at the output end of the inductor, the current flowing through the inductor will increase. Therefore, when the control level circuit CL senses that the current Ia of the inductor In-a is greater than a preset current value (the current value that the preset motor model should have when the input end has the electrical potential Vd-a), the control level circuit CL immediately generate the trigger signal S_{E,Φ} to control the inverter circuit IV to change the electrical potential Ve-a at the output end of the inductor In-a from low potential to high potential. The current Ia flowing through the inductor In-a remains unchanged through this operation. If the control level circuit CL controls the inverter circuit IV to maintain the electrical potential Ve-a at the output end of the inductor In-a low for a compensation time and then following the change of the electrical potential Vd-a at the input end to a high potential, it will cause the current Ia higher than the preset current value increases further, thereby deteriorating the simulation state of the motor. Therefore, in this embodiment, the current Ia flowing through the inductor In-a remains unchanged through this operation, and the current Ia of the inductor In-a can be maintained from deteriorating.

Refer to FIG. 3 and FIG. 8. In one embodiment of the disclosure, the step of providing the trigger signal S_{E,Φ} according to the change of the electrical potential Vd-a at the input end of the inductor In-a and the value of current Ia passing through the inductor In-a to determine change of the electrical potential Ve-a at the output end of the inductor In-a includes: step S212: when it is sensed that the current Ia of the inductor In-a is greater than a preset current value, and step S232: When the electrical potential at the input end of the inductor In-a changes from high potential to low potential (as Vd-a in FIG. 3), execute step S252: the motor emulator circuit EME maintains the electrical potential at the output end of the inductor In-a high for a compensation time t2 and then changes from high potential to low potential (as Ve-a in FIG. 3).

In detail, according to the operating principle of the inductor, if the electrical potential at the input end of the inductor is less than the electrical potential at the output end of the inductor, the value of current flowing through the inductor will decrease. Therefore, when the control level circuit CL senses that the current Ia of the inductor In-a is greater than a preset current value (the current value that the preset motor model should have when the input end has the electrical potential Vd-a), the control level circuit CL controls the inverter circuit IV to maintain the electrical potential Ve-a at the output end of the inductor In-a high for a compensation time and then follows the change of the electrical potential Vd-a at the input end to a low potential. The current Ia flowing through the inductor In-a is reduced through this operation to obtain compensation. The value of the compensation time t2 can be determined by the difference between the current Ia of the inductor In-a and the preset current value, the difference between the electrical potential Vd-a at the input end and the electrical potential Ve-a at the output end, and the inductance of the inductor In-a. The value is determined to reduce the error of the current simulated by the motor emulator EME.

In detail, as shown in FIG. 8, when it is sensed that the current Ia of the inductor In-a is equal to a preset current value, the process returns to step S211 to continue detection.

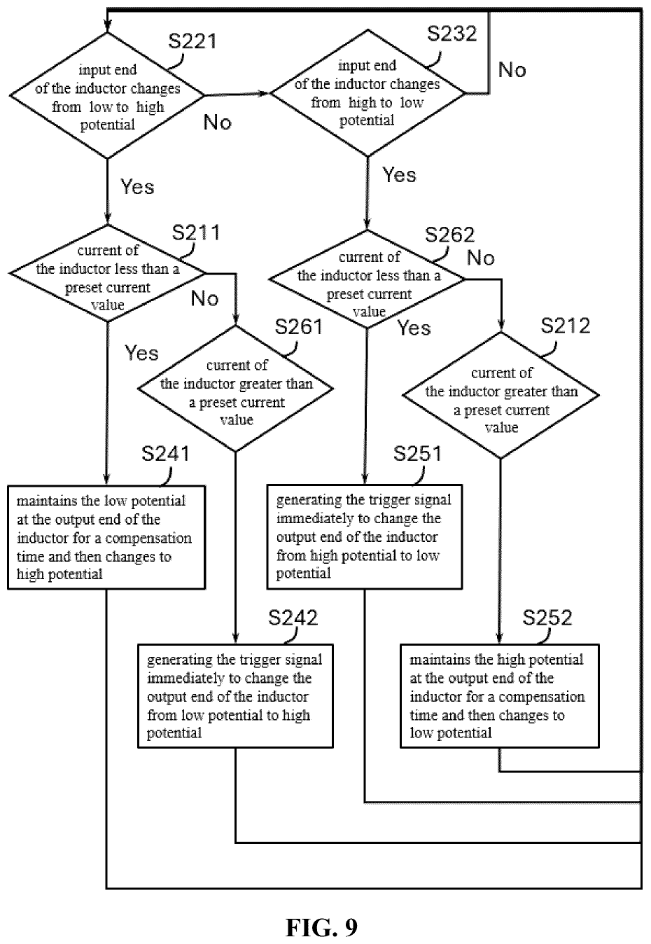

Referring to FIG. 9, a schematic flowchart of a control method of a motor emulator according to another embodiment of the disclosure is shown. It should be noted that, as shown in FIG. 9, the order of step S211 and step S221 can be reversed, that is, the current value of the inductor is compared after sensing the change of the electrical potential at the input end of the inductor. It can be more easily implemented that the electrical potential at the output end of the inductor follows the electrical potential at the input end. Similarly, the order of step S212 and step S232 can be reversed, that is, the current value of the inductor is compared after sensing the change of the electrical potential at the input end of the inductor. It is easier to implement that the electrical potential at the output end of the inductor follows the electrical potential at the input end.

In detail, refer to FIG. 1, FIG. 2 and FIG. 9. In one embodiment of the disclosure, the step S200 of providing the trigger signal S_{E,Φ} based on the change of electrical potential at the input end of the inductor In-a and the value of current Ia passing through the inductor In-a to determine change of the electrical potential Ve-a at the output end of the inductor In-a includes: step S221: when the electrical potential at the input end of the inductor In-a changes from low potential to high potential (as Vd-a in FIG. 2), and step S211: when sensing the current Ia of the inductor In-a is less than a preset current value, and then execute step S241: the motor emulator circuit EME maintains the electrical potential at the output end of the inductor In-a low for a compensation time t1 and then changes it from low potential to high potential (as Ve-a in FIG. 2).

Refer to FIG. 1, FIG. 2 and FIG. 9. In one embodiment of the disclosure, the step of providing the trigger signal S_{E,Φ} according to the change of the electrical potential Vd-a at the input end of the inductor In-a and the value of current Ia passing through the inductor In-a to determine change of the electrical potential Ve-a at the output end of the inductor In-a include: step S232: when the electrical potential at the input end of the inductor In-a changes from high potential to low potential (as Vd-a in FIG. 2), and step S262: when it is detected that the current Ia of the inductor In-a is less than a preset current value, and then execute step S251: immediately generating the trigger signal to change the electrical potential at the output end of the inductor from high potential to low potential (as Ve-a in FIG. 2).

Refer to FIG. 3 and FIG. 9 together. In one embodiment of the disclosure, The step of providing the trigger signal S_{E,Φ} according to the change of the electrical potential Vd-a at the input end of the inductor In-a and the value of current Ia passing through the inductor In-a to determine change of the electrical potential Ve-a at the output end of the inductor In-a includes: step S221: when the electrical potential at the input end of the inductor In-a changes from low potential to high potential (Vd-a in FIG. 3), and step S261: when sensing the current Ia of the inductor In-a is greater than a preset current value. Then execute Step S242: immediately generating the trigger signal S_{E,Φ} to change the electrical potential at the output end of the inductor In-a from low potential to high potential (Ve-a in FIG. 3).

Refer to FIG. 3 and FIG. 9 together. In one embodiment of the disclosure, the step of providing the trigger signal S_{E,Φ} according to the change of the electrical potential Vd-a at the input end of the inductor In-a and the value of current Ia passing through the inductor In-a to determine change of the electrical potential Ve-a at the output end of the inductor In-a includes: when step S232: the electrical potential at the input end of the inductor In-a changes from high potential to low potential (as Vd-a in FIG. 3), and step S212: when it is sensed that the current Ia of the inductor In-a is greater than a preset current value, and then execute step S252: the motor emulator circuit EME maintains the electrical potential at the output end of the inductor In-a high for a compensation time t2 and then changes it from high potential to low potential. (as Ve-a in FIG. 3).

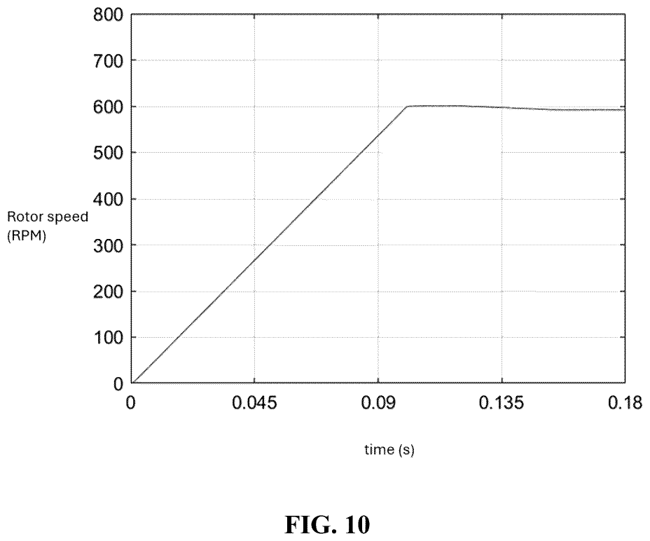

FIG. 10 is a schematic diagram of a rotor speed in a simulation scenario of a motor emulator and a motor driver according to an embodiment of the disclosure. In detail, the power level circuit PL and control level circuit CL models of the motor driver DUT and motor emulator EME are established in Simulink simulation software. The simulation situation is: the motor emulator EME starts to accelerate to 600 rpm (electrical frequency 100 Hz) at 0 seconds, and then increases the torque load to 50 N·m at 0.12 seconds. The motor parameters are as follows: stator resistance Rs: 0.072, friction coefficient B: 0.007 N·m·s/rad, moment of inertia J: 0.0383 kg·m², d-axis inductance Ld: 177×10⁻⁶ μH, q-axis inductance Lq: 183×10⁻⁶ μH, flux constant λm: 0.0569 Wb, pole pair number N_{P}: 10. FIG. 10 shows a schematic diagram of the rotor speed in the above simulation scenario.

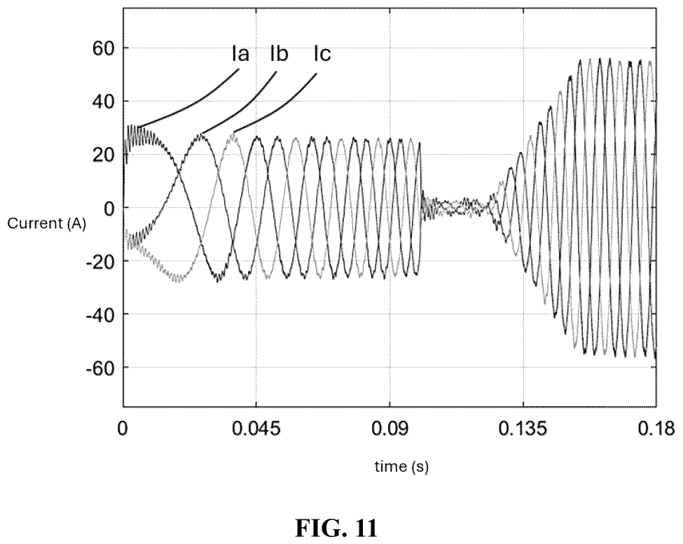

FIG. 11 illustrates a schematic diagram of the three-phase current in the simulation scenario of FIG. 10. In detail, the three-phase currents Ia, Ib, and Ic of the motor emulator EME maintain a current amplitude of from +20 amperes to −20 amperes during the acceleration to 600 rpm. The current amplitude is the smallest during constant speed operation, and when the torque load is added to 50 N·m, the current amplitudes of the three phases gradually increase.

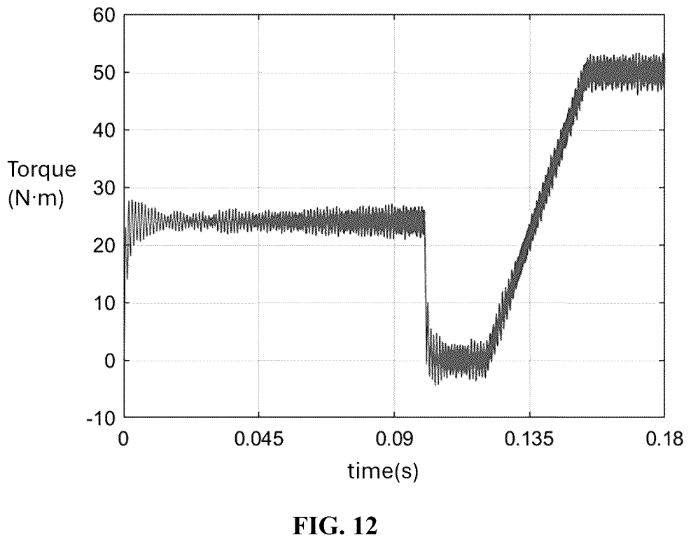

FIG. 12 illustrates a schematic diagram of the torque in the simulation scenario of FIG. 10. In detail, the torque of the motor emulator EME is maintained at about 25 Newton meters during acceleration to 600 rpm. The torque is minimum and close to zero when running at constant speed. In the process of adding torque load to 50 N·m, the torque value gradually increases.

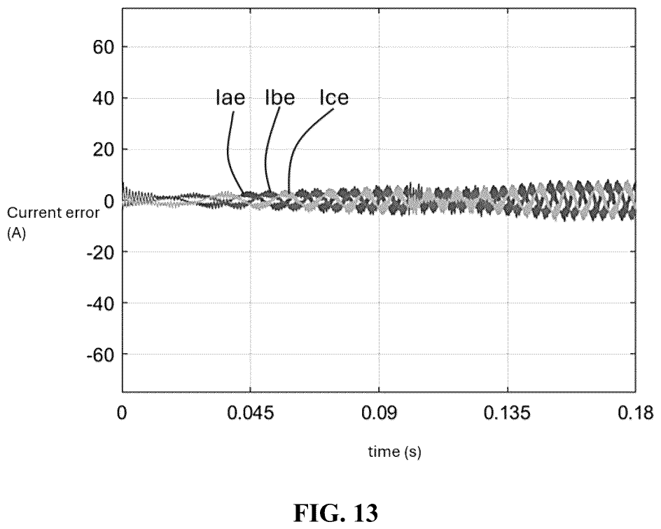

FIG. 13 is a schematic diagram of the simulation results of the current error in the simulation scenario of FIG. 10. In detail, the error currents Iae, Ibe, and Ice of the three phases are all maintained within a range of less than ±10 amps.

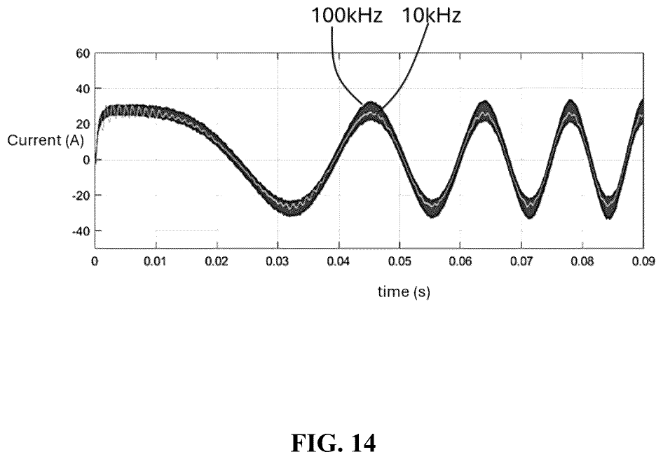

FIG. 14 illustrates a comparison of simulated current waveforms during rotor acceleration between a motor emulator using a switching frequency of 10 kHz according to an embodiment of the disclosure and a motor emulator using a frequency of 100 kHz in the prior art. It can be clearly seen that the ripple of the current Ia (light-colored curve) of the motor emulator using a switching frequency of 10 kHz in the disclosure is smaller than the ripple of the current (dark-colored curve) of the motor emulator using a switching frequency of 100 kHz in the prior art.

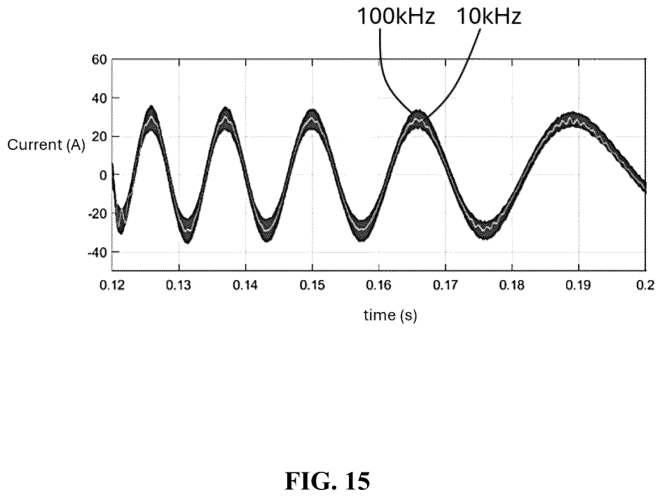

FIG. 15 illustrates a comparison of simulated current waveforms during rotor deceleration between a motor emulator using a switching frequency of 10 kHz according to an embodiment of the disclosure and a motor emulator using a frequency of 100 kHz in the prior art. It can be clearly seen that the ripple of the current Ia (light-colored curve) of the motor emulator using a switching frequency of 10 kHz in the disclosure is smaller than the ripple of the current (dark-colored curve) of the motor emulator using a switching frequency of 100 kHz in the prior art.

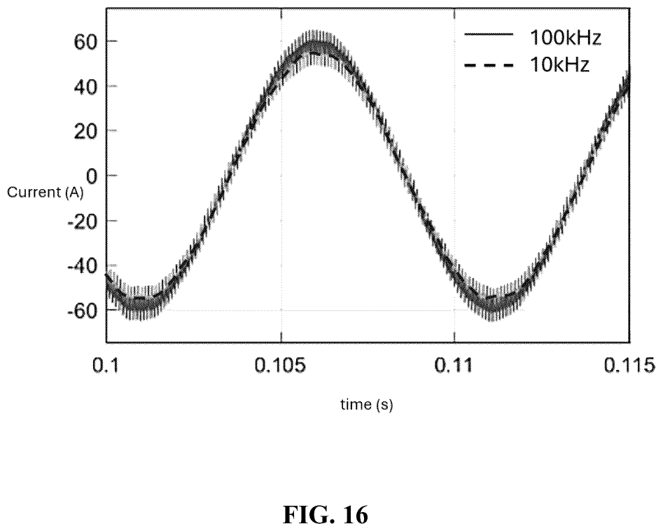

FIG. 16 illustrates a comparison of simulated current waveforms between a motor emulator using a switching frequency of 10 kHz according to an embodiment of the disclosure and a motor emulator using a frequency of 100 kHz in the prior art at a rotor speed of 600 rpm and a torque of 50 Newton meters. It can be clearly seen that the ripple of the current Ia of the motor emulator using the switching frequency of 10 kHz in the disclosure is smaller than the ripple of the current Ia of the motor emulator using the switching frequency of 100 kHz in the prior art.

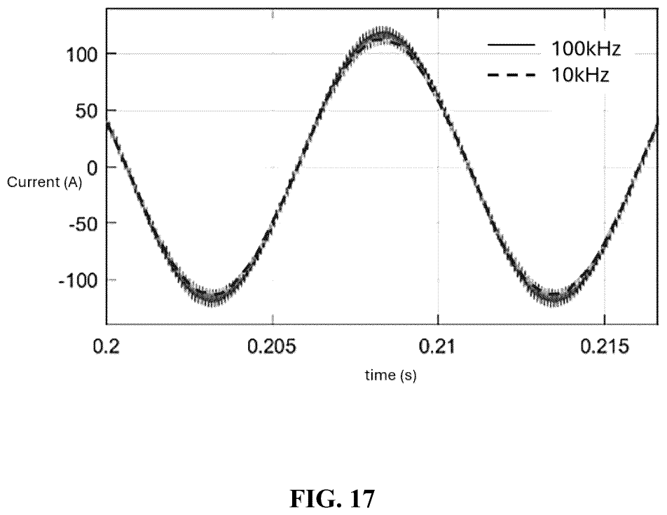

FIG. 17 illustrates a comparison of simulated current waveforms between a motor emulator using a switching frequency of 10 kHz according to an embodiment of the disclosure and a motor emulator using a frequency of 100 kHz in the prior art at a rotor speed of 600 rpm and a torque of 100 Newton meters. It can be clearly seen that the ripple of the current Ia of the motor emulator using the switching frequency of 10 kHz in the disclosure is smaller than the ripple of the current Ia of the motor emulator using the switching frequency of 100 kHz in the prior art. It can be seen from the simulation curves of FIGS. 14 to 17 that the motor emulator according to the embodiment of the disclosure has lower switching frequency, lower switching loss, and smaller current ripples than the conventional high-frequency switching motor emulator.

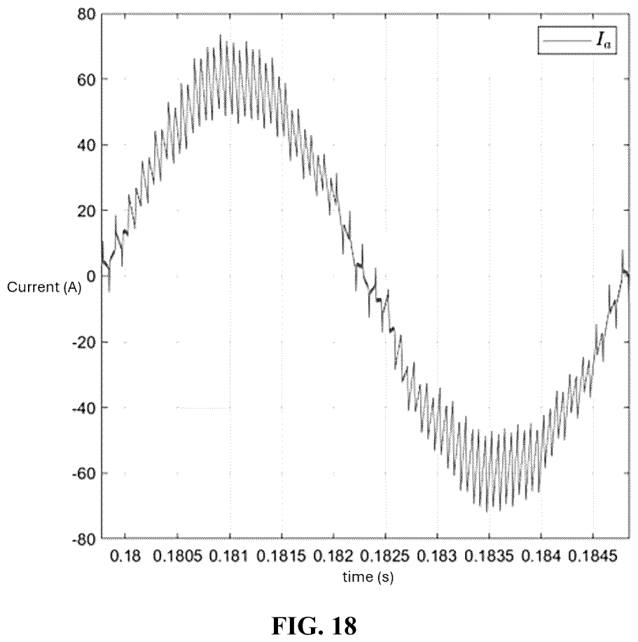

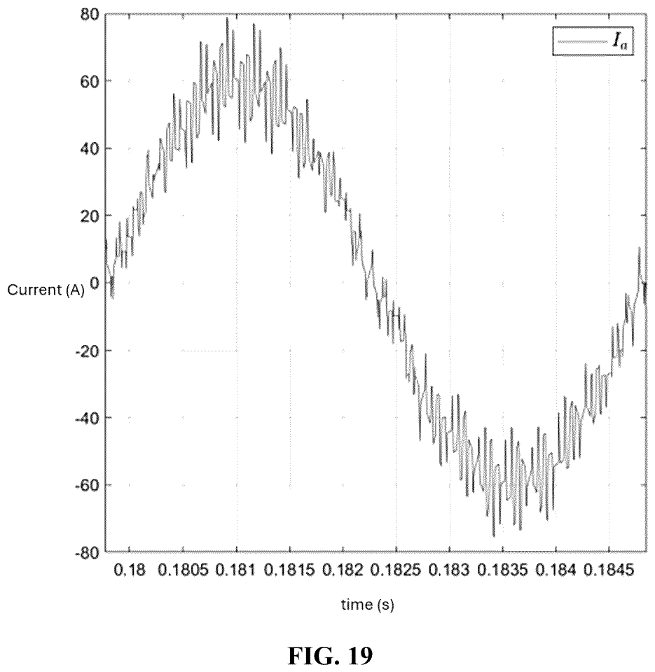

In addition, using a higher switching frequency in the conventional technology will cause larger ripples, but this does not mean that the ripples can be reduced by directly lowering the switching frequency without making any changes. Referring to FIGS. 18 and 19, FIG. 18 illustrates the current waveform of a motor emulator according to the prior art at a frequency of 100 kHz under a simulation scenario. FIG. 19 illustrates a current waveform at a frequency of 10 kHz by a motor emulator based on the prior art under a simulation scenario. It can be found from the waveform curves in FIGS. 18 and 19 that using the motor emulator of the conventional technology, even if the switching frequency is reduced from 100 kHz to 10 kHz, the ripples are still very large and cannot reach the effect of lower ripple like the motor emulator of the embodiment of the disclosure (see FIG. 5 and FIG. 6).

In comparison with prior art, the disclosed motor emulator provides the trigger signal based on change of electrical potential at an input end of the inductor and a value of a current passing through the inductor to control the inverter circuit to change the electrical potential at the output end of the inductor, so that an electrical potential at the output end of the inductor follows the change of the electrical potential at the input end of the inductor to adjust the current passing through the inductor. The motor emulator can operator at the same switching frequency with the motor driver without further signal from the motor driver. The motor emulator can on one hand switch the current with lower frequency to reduce switching lose and on the other hand compensate current error rapidly to increase accuracy of current control and avoid the issue in the prior art.

The above description is to illustrate the characteristics of the disclosure through preferred embodiments. The purpose is to enable those skilled in the art to understand the content of the disclosure and implement it accordingly, but not to limit the patent scope of the application. Therefore, any other equivalent modifications or modifications that do not depart from the technical ideas disclosed in this application shall still be included in the claim scope described below.

What is claimed is:

1. A control method of a motor emulator, comprising:
receiving an electrical potential signal of a motor driver by a power level circuit of a motor emulator, wherein the power level circuit at least comprises an inductor, and an input end of the inductor is configured to receive the electrical potential signal of the motor driver; and
providing a trigger signal based on a change of electrical potential at the input end of the inductor and a value of a current passing through the inductor to determine a change of electrical potential at an output end of the inductor, so that an electrical potential at the output end of the inductor follows the change of the electrical potential at the input end of the inductor to adjust the current passing through the inductor.

2. The control method of the motor emulator according to claim 1, wherein the step of providing the trigger signal based on the change of the electrical potential at the input end of the inductor and the value of the current passing through the inductor to determine the change of the electrical potential at the output end of the inductor comprises:
when the value of the current passing the inductor is less than a preset current value and the electrical potential at the input end of the inductor changes from low to high, the motor emulator keeps a low electrical potential at the output end of the inductor for a preset duration and then changes the electrical potential from low to high.

3. The control method of the motor emulator according to claim 1, wherein the step of providing the trigger signal based on the change of the electrical potential at the input end of the inductor and the value of the current passing through the inductor to determine the change of the electrical potential at the output end of the inductor comprises:
when the value of the current passing the inductor is less than a preset current value and the electrical potential at the input end of the inductor changes from high to low, the motor emulator provides the trigger signal immediately to change the electrical potential at the output end of the inductor from high to low.

4. The control method of the motor emulator according to claim 1, wherein the step of providing the trigger signal based on the change of the electrical potential at the input end of the inductor and the value of the current passing through the inductor to determine the change of the electrical potential at the output end of the inductor comprises:
when the value of the current passing the inductor is greater than a preset current value and the electrical potential at the input end of the inductor changes from low to high, the motor emulator provides the trigger signal immediately to change the electrical potential at the output end of the inductor from low to high.

5. The control method of the motor emulator according to claim 1, wherein the step of providing the trigger signal based on the change of the electrical potential at the input end of the inductor and the value of the current passing through the inductor to determine the change of the electrical potential at the output end of the inductor comprises:
when the value of the current passing the inductor is greater than a preset current value and the electrical potential at the input end of the inductor changes from high to low, the motor emulator keeps a high electrical potential at the output end of the inductor for a preset duration and then changes the electrical potential from high to low.

6. A motor emulator configured to receive an electrical potential signal of a motor driver, comprising:
a power level circuit at least comprising an inductor and an inverter circuit configured to provide an electrical potential to an output end of the inductor; and
a control level circuit configured to provide a trigger signal based on a change of electrical potential at an input end of the inductor and a value of a current passing through the inductor to determine a change of the electrical potential at the output end of the inductor, so that an electrical potential at the output end of the inductor follows the change of the electrical potential at the input end of the inductor to adjust the current passing through the inductor.

7. The motor emulator according to claim 6, wherein the control level circuit is configured to control the inverter circuit to keep a low electrical potential at the output end of the inductor for a preset duration and then changes the electrical potential from low to high when the value of the current passing the inductor is less than a preset current value and the electrical potential at the input end of the inductor is changed from low to high.

8. The motor emulator according to claim 6, wherein the control level circuit is configured to provide the trigger signal immediately to control the inverter circuit to change the electrical potential at the output end of the inductor from high to low when the value of the current passing the inductor is less than a preset current value and the electrical potential at the input end of the inductor is changed from high to low.

9. The motor emulator according to claim 6, wherein the control level circuit is configured to provide the trigger signal immediately to control the inverter circuit to change the electrical potential at the output end of the inductor from low to high when the value of the current passing the inductor is greater than a preset current value and the electrical potential at the input end of the inductor is changed from low to high.

10. The motor emulator according to claim 6, wherein the control level circuit is configured to control the inverter circuit to keep a high electrical potential at the output end of the inductor for a preset duration and then changes the electrical potential from high to low when the value of the current passing the inductor is greater than a preset current value and the electrical potential at the input end of the inductor is changed from high to low.

11. The power module according to claim 6, wherein the control level circuit comprises: a voltage sensing module, a current sensing module, a motor model library, and a control module, the voltage sensing module is configured to detect the change of electrical potential at the input end of the inductor, the current sensing module is configured to detect the current passing through the inductor, and the control module is configured to retrieve current data corresponding to the preset motor model from the motor model library based on the electrical potential detected by the voltage sensing module and compare it with the current value obtained by the current sensing module to provide the trigger signal.

12. The power module according to claim 11, wherein the control level circuit further comprises a pulse width modulation module configured to provide pulse width modulation signal to turn on or off the inverter circuit based on a signal from the control module and the change of electrical potential at the input end of the inductor.

13. The power module according to claim 6, wherein the power level circuit comprises a DC voltage supply module to provide the electrical potential at the output end of the inductor through the inverter circuit.

14. The power module according to claim 13, wherein the DC voltage supply module and a DC voltage supply module of the motor driver are grounded together and provide a same DC electrical potential.

15. The power module according to claim 13, wherein the DC voltage supply module and a DC voltage supply module of the motor driver are grounded together and provide different DC potentials, and the power level circuit further comprises a zero sequence filter circuit disposed between the output end of the inductor and the inverter circuit.

16. The power module according to claim 13, wherein the DC voltage supply module and a DC voltage supply module of the motor driver are isolated from each other.
